(19) United States
(12) Patent Application Publication
(10) Pub. No.: US 2024/0040742 A1
(43) Pub. Date: Feb. 1, 2024

(54) SYSTEM FOR THERMAL TREATMENT OF AN ELECTRICAL AND/OR ELECTRONIC COMPONENT

(71) Applicant: Valeo Systemes Thermiques, Le Mesnil-Saint-Denis (FR)

(72) Inventors: Yolanda Bravo, Zaragoza (ES); Jeremy Blandin, Le Mesnil-Saint-Denis Cedex (FR); Cédric De Vaulx, Le Mesnil-Saint-Denis Cedex (FR); Patrick Leblay, Le Mesnil-Saint-Denis Cedex (FR); Kamel Azzouz, Le Mesnil-Saint-Denis Cedex (FR); Julien Tissot, Le Mesnil-Saint-Denis Cedex (FR)

(73) Assignee: Valeo Systemes Thermiques, Le Mesnil-Saint-Denis (FR)

(21) Appl. No.: 18/257,402

(22) PCT Filed: Dec. 6, 2021
(86) PCT No.: PCT/EP2021/084439

§ 371 Date: Jun. 14, 2023

(30) Foreign Application Priority Data
Dec. 14, 2020 (FR) 2013206

(51) Int. Cl. H05K 7/20

(52) U.S. Cl. CPC H05K 7/20254

(57) ABSTRACT

The present invention relates to a system (100) for thermal treatment of at least one electrical and/or electronic component, comprising at least one housing (110) that accommodates at least one heat exchanger (130), the electrical and/or electronic component (120) being suitable for being accommodated in the housing and for resting on the at least one heat exchanger (130), the heat exchanger (130) comprising at least one network of microfibres (150), the microfibres (151) being suitable for having a refrigerant fluid flowing through them and the heat exchanger (130) being suitable for being in contact with at least two adjacent faces (121, 122) of the electrical and/or electronic component (120).

The field of the present invention is that of thermally treating electrical and/or electronic components likely to heat up when they operate. More specifically, the present invention relates to thermally regulating electrical and/or electronic components in various fields of application, such as computer servers or motor vehicle batteries. The term “thermal regulation” is understood herein to mean both cooling of the relevant electrical and/or electronic component and preheating of this component, with such preheating allowing the start-up of the electrical and/or electronic component in question to be facilitated.

By way of an example, in the automotive field, current environmental constraints encourage automotive manufacturers to develop the market for electric and hybrid vehicles, which, when operating, generate less polluting emissions than conventional heat engine vehicles.

These electric and hybrid vehicles are propelled by means of an electric motor powered by electric energy stored in batteries arranged in the vehicle. In order to reduce the time required to recharge these batteries, new apparatus have been set-up in order to allow a “fast charge” for these batteries, i.e., a full charge, or almost full charge, in a few tens of minutes.

In general, these batteries tend to heat up during use, and the electric and hybrid vehicles are thus equipped with thermal regulation apparatus configured to exchange heat with these batteries in order to discharge their calories. These heat exchangers are generally formed by rigid metal plates that define ducts for circulating a heat-transfer fluid adapted for capturing calories from the batteries.

In the fast charge phase of the batteries, this phenomenon worsens, i.e., the batteries can then reach excessive temperatures that risk permanently damaging them. Thermal regulation apparatus like the heat exchangers mentioned above are currently insufficient for overcoming this major disadvantage.

These thermal regulation apparatus are also hardly effective, or not effective, when miniaturized electrical components need to be thermally treated, such as those that can be found in computer servers, for example. In addition, the materials used to manufacture these heat exchangers are very heavy and the heat exchangers that are obtained are also bulky. The present invention falls within this context by proposing a system for thermally treating an electrical and/or electronic component that integrates heat exchangers that are lighter than the heat exchangers of the prior art, but that have at least equivalent thermal performance capabilities.

An aim of the present invention thus relates to a system for thermally treating at least one electrical and/or electronic component, comprising at least one housing that accommodates at least one heat exchanger, with the electrical and/or electronic component being adapted for being accommodated in the housing and for resting on the at least one heat exchanger, the heat exchanger comprising at least one microfiber network, the microfibers being adapted for being traversed by a coolant and the heat exchanger being adapted for being in contact with at least two adjacent faces of the electrical and/or electronic component.

The term “microfiber” is understood herein to mean a hollow tubular structure adapted for being traversed by the coolant. According to the invention, the heat exchanger is thus configured to exchange heat between the coolant that circulates in the microfibers and the electrical and/or electronic component that rests on this heat exchanger. For example, these microfibers can be made of a polymer that makes them deformable, i.e., having the ability to undergo and to withstand mechanical stresses without being damaged. Advantageously, this deformability of the microfibers allows the microfibers to be pressed against the electrical and/or electronic component in an optimized manner, thus optimizing the available heat exchange surface and therefore the exchange of heat that is effectively carried out. Furthermore, this deformability of the microfibers ensures that the heat exchanger makes contact with the two adjacent faces of the electrical and/or electronic component, also optimizing the exchange of heat between these components, i.e., improving the cooling of the electrical and/or electronic component.

Moreover, the term “resting” is understood to mean the fact that the heat exchanger is adapted for mechanically supporting the electrical and/or electronic component. In other words, the heat exchanger is at least partially rigid.

According to one embodiment of the invention, the heat exchanger comprises the microfiber network at least partially surrounded by a deformable material. It is understood from the above that, according to this embodiment of the invention, this material is deformable but is resistant enough to support the weight of the electrical and/or electronic component that is intended to rest on this heat exchanger, without being damaged.

According to one feature of the invention, the heat exchanger comprises at least one rigid component. The term “rigid component” is understood herein to mean a component that is rigid enough to support an electrical and/or electronic component. For example, the deformable material can comprise the rigid component. Alternatively, the rigid component can be adapted for being interposed between the heat exchanger and the electrical and/or electronic component. For example, the rigid component can assume the form of a metal plate. For example, the rigid component can be an aluminum plate.

According to one feature of the invention, the thermal treatment system comprises two heat exchangers, with at least one electrical and/or electronic component being intended to rest, respectively, on each of these heat exchangers, with each heat exchanger comprising at least one microfiber network and each heat exchanger being adapted for being in contact with at least two adjacent faces of the electrical and/or electronic component that is intended to rest thereon.

According to one feature of the invention, at least one of the faces of one of the electrical and/or electronic components adapted for being covered by one of the heat exchangers is intended to be arranged facing one of the faces of the other electrical and/or electronic component adapted for being covered by the other heat exchanger. Advantageously, such an arrangement allows a thermal barrier to be created between two juxtaposed electrical and/or electronic components, thus avoiding a transfer of calories between these two electrical and/or electronic components that would reduce the efficiency of the cooling carried out by the heat exchangers that are adapted for forming a support for these electrical and/or electronic components.

According to one embodiment of the invention, the heat exchanger comprises at least one first microfiber network and at least one second microfiber network distinct from the first microfiber network, with the first microfiber network being adapted for mainly extending facing a first face of the electrical and/or electronic component and the second microfiber network being adapted for mainly extending facing a second face of the electrical and/or electronic component, with the first face of the electrical and/or electronic component being adjacent to the second face of this electrical and/or electronic component.

According to one feature of this embodiment of the invention, the first microfiber network mainly extends in a first plane and the second microfiber network mainly extends in a second plane, with the first plane being able to be perpendicular to the second plane. In other words, the first plane and the second plane intersect each other.

Alternatively, the heat exchanger can comprise a single microfiber network, with the microfibers of this single microfiber network each extending in a first plane and in a second plane intersecting each other. In other words, according to this alternative, the same microfiber is intended to be arranged facing, at the same time, the two adjacent faces of the electrical and/or electronic component adapted for being covered by the heat exchanger. The same microfiber thus comprises at least one first portion adapted for being arranged facing a first face of the electrical and/or electronic component and at least one second portion adapted for being arranged facing a second face of the electrical and/or electronic component, with the second face being adjacent to the first face.

Optionally, the heat exchanger can extend over an entire longitudinal dimension of the electrical and/or electronic component intended to rest thereon. The term “longitudinal dimension” is understood to mean a dimension of the relevant electrical and/or electronic component measured parallel to a main axis of extension of this electrical and/or electronic component. For example, the first face of the electrical and/or electronic component and the second face of the electrical and/or electronic component can have a substantially longitudinal junction edge, with the heat exchanger on which the electrical and/or electronic component is intended to rest being configured to extend over an entire longitudinal dimension of this electrical and/or electronic component.

According to one embodiment of the invention, the microfibers of the microfiber network are evenly arranged within the heat exchanger.

According to another embodiment of the invention, the microfibers of the microfiber network are randomly arranged within the heat exchanger.

According to one feature of the invention, the housing accommodates at least one fluid supply base of the heat exchanger, with the heat exchanger being configured to exchange heat between the coolant and the electrical and/or electronic component, with the supply base being configured to allow routing, and/or respectively discharging, of the coolant into, and/or respectively out of, the microfibers of the heat exchanger. Advantageously, the supply base is integrally formed with the housing. In other words, the supply base and the housing then form a single assembly that cannot be separated without damaging the supply base and/or the housing.

According to one feature of the invention, each microfiber of the heat exchanger comprises at least one inlet channel and at least one outlet channel, with the inlet channels of the microfibers being fluidly connected to an inlet collector box configured to distribute the coolant within the microfibers and the outlet channels of the microfibers being fluidly connected to an outlet collector box configured to collect the coolant leaving the microfibers. Advantageously, all the inlet channels of all the microfibers of the heat exchanger can be fluidly connected to the same inlet collector box and all the outlet channels of all the microfibers of the heat exchanger can be fluidly connected to the same outlet collector box.

According to one feature of the invention, the inlet collector box is fluidly connected to the supply base and the outlet collector box is fluidly connected to the supply base. According to an example of the application of the invention, the supply base comprises at least one supply zone configured to supply the inlet collector box with coolant and at least one collection zone configured to collect the coolant leaving the outlet collector box. Advantageously, the supply base can be configured to be fluidly connected to a plurality of inlet collector boxes and to a plurality of outlet collector boxes. In other words, the present invention advantageously allows the “connection”, i.e., fluid communication, of a plurality of collector boxes, i.e., a plurality of heat exchangers, on the same supply base, with this supply base itself being integral with the housing of the thermal treatment system. In other words, the present invention allows the thermal treatment system to be implemented quickly and so as to be easily adaptable to various configurations.

For example, the thermal treatment system thus can comprise a plurality of heat exchangers distributed over at least two rows, with the supply base extending between the two rows of heat exchangers. It is understood that, according to this example, each heat exchanger of each of the two rows of heat exchangers is fluidly connected to the supply base by means of at least one inlet collector box and at least one outlet collector box.

The present invention also relates to an electrical energy storage device comprising at least one electrical energy storage component and at least one thermal treatment system as mentioned above and wherein the at least one electrical and/or electronic component that rests on the at least one heat exchanger of the thermal treatment system is an electrical energy storage component.

The present invention also relates to a vehicle comprising at least one electrical energy storage device as mentioned above.

Further features, details and advantages of the invention will become more clearly apparent from the following description, on the one hand, and from several embodiments that are provided by way of a non-limiting indication with reference to the accompanying schematic drawings, on the other hand, in which:

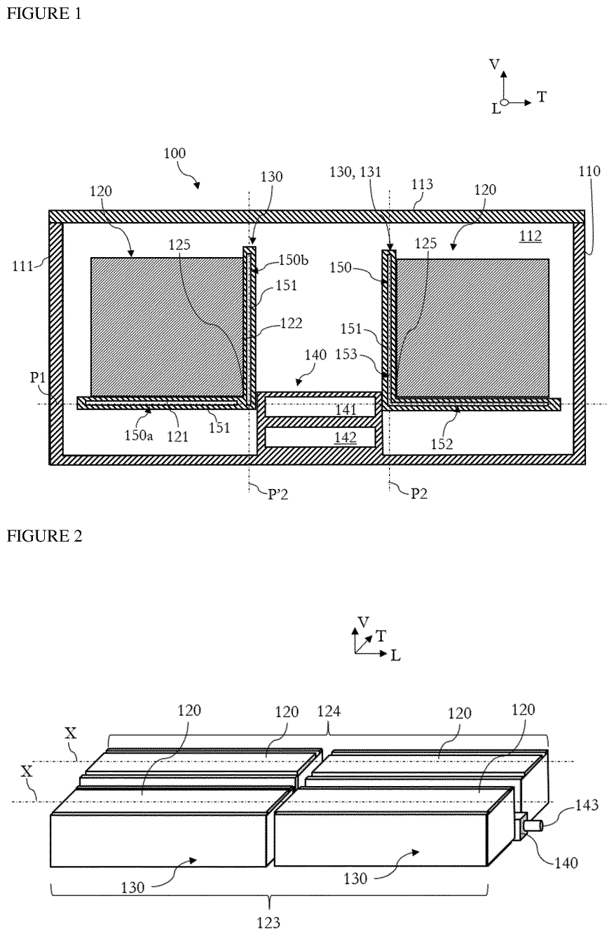

FIG. 1 schematically illustrates a vertical cross-sectional view of a system for thermally treating an electrical and/or electronic component according to a first embodiment of the invention;

FIG. 2 schematically illustrates, as a perspective view, the thermal treatment system according to a second embodiment of the invention, with the thermal treatment system being shown together with a plurality of electrical and/or electronic components;

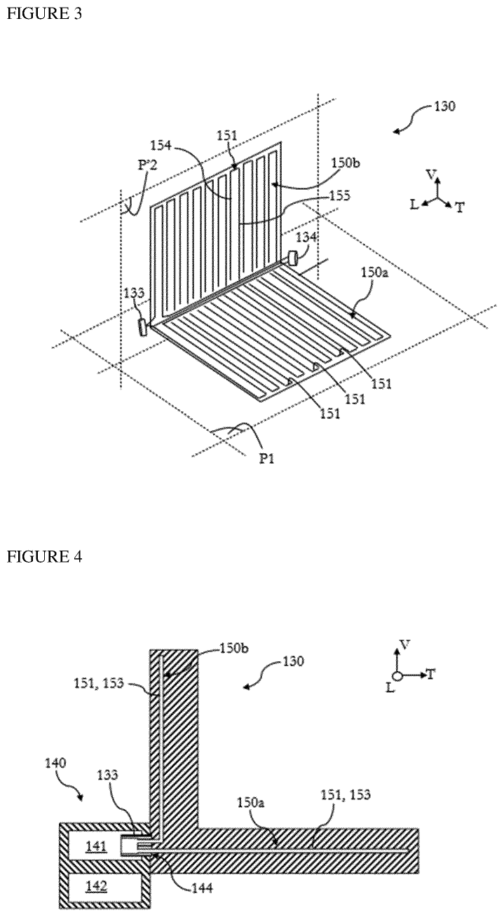

FIG. 3 schematically illustrates, as a perspective view, a heat exchanger of the thermal treatment system according to the invention;

FIG. 4 schematically illustrates a vertical cross-sectional view of a heat exchanger of the thermal treatment system according to the first embodiment illustrated with a fluid supply base of this thermal treatment system.

Throughout the remainder of the description, the terms “electrical and/or electronic component” and “electrical component” will be used without distinction. The denominations “longitudinal”, “vertical” and “transversal” refer to the orientation of the considered object within an L, V, T reference frame illustrated in the figures, in which a longitudinal direction corresponds to a direction parallel to the longitudinal axis L, a vertical direction corresponds to a direction parallel to the vertical axis V and a transverse direction corresponds to a direction parallel to the transverse axis T, with the longitudinal axis L, the vertical axis V and the transverse axis T being perpendicular in pairs. In this reference frame, a vertical section corresponds to a section made in a vertical and transverse plane, i.e., a plane in which the vertical axis V and the transverse axis T of the illustrated trihedron are inscribed.

The following description describes a thermal treatment system 100 according to the invention, with this thermal treatment system 100 being adapted for thermally treating at least one electrical and/or electronic component 120. More specifically, the figures on which the following description is based provide an example of an application of the invention in which the electrical and/or electronic component 120 is an electrical energy storage component, but it is understood that the description applies mutatis mutandis to any other electrical and/or electronic component 120 adapted for being heat-treated by a thermal treatment system according to the invention. For example, this electrical and/or electronic component can be an electrical component of a computer server.

FIG. 1 is a vertical cross-sectional view of the thermal treatment system 100 according to the invention. This thermal treatment system 100 comprises a housing 110, a peripheral wall 111 of which defines an internal volume 112 closed by a cover 113, with this internal volume 112 accommodating at least one electrical and/or electronic component 120, at least one heat exchanger 130 on which the at least one electrical and/or electronic component 120 rests i.e., this electrical and/or electronic component 120 is at least partially supported by the at least one heat exchanger 130, and at least one fluid supply base 140 of the heat exchanger 130.

According to the illustrated example, the thermal treatment system 100 comprises at least two heat exchangers 130 that respectively accommodate an electrical and/or electronic component 120. In other words, an electrical and/or electronic component 120 rests on each of the heat exchangers 130. The following description relates to a heat exchanger 130 and the electrical and/or electronic component 120 that rests on this heat exchanger 130, but it is understood that, unless otherwise indicated, it applies to all the heat exchangers 130 and electrical and/or electronic components 120 of the thermal treatment system 100 according to the invention. Similarly, the references used on one of the electrical and/or electronic components 120 and on one of the heat exchangers 130 are directly mutually transferable.

The heat exchanger 130 is thus configured to exchange heat between a coolant and the electrical and/or electronic component 120 that rests thereon. In other words, a coolant circulates in the heat exchanger 130, with this coolant being able to convey calories and to exchange them with its environment, in this case with the electrical and/or electronic component 120 that rests on this heat exchanger 130. According to the invention, this heat exchange can be carried out by means of a coolant that may or may not change state when exchanging calories.

As described in further detail hereafter, the heat exchanger 130 is equipped with at least one inlet collector box configured to distribute the coolant in the heat exchanger 130 and at least one outlet collector box configured to collect the coolant that leaves this heat exchanger. These inlet and outlet collector boxes are also fluidly connected to the supply base 140. Advantageously, this supply base 140 is integrally formed with the housing 110. In other words, the housing 110 and the supply base 140 form a single assembly that cannot be separated without damaging the housing 110 and/or the supply base 140.

According to the example illustrated herein, this supply base 140 is shared in a supply zone 141 configured to allow the coolant to be conveyed to at least one inlet collector box of the heat exchanger 130 and at least one collection zone 142 configured to collect the coolant that leaves the outlet collector box of this heat exchanger 130. It is understood that the depiction of this supply zone 141 and of this collection zone 142 is highly schematic in FIG. 1 and must not be understood to be limiting the invention. In other words, this supply zone 141 and this collection zone 142 can be arranged according to any arrangement without departing from the scope of the present invention, on the condition that the inlet collector box and the outlet collector box of the heat exchanger 130 can be fluidly connected thereto.

According to the invention, the heat exchanger 130 comprises at least one microfiber network 150 fluidly connected to the supply base 140 via the inlet and outlet collector boxes mentioned above. In other words, the heat exchanger 130 comprises a plurality of microfibers 151, each fluidly connected to the supply base 140, via the inlet and outlet collector boxes mentioned above. These microfibers 151 are depicted highly schematically and as an exploded view in FIG. 1.

These microfibers 151 are configured to be traversed by the coolant and form a heat exchange surface of the heat exchanger, i.e., a zone of this heat exchanger 130 within which the heat exchange mentioned above is carried out. The term “microfiber” is understood herein to mean a hollow tubular structure with a constant, or substantially constant, cross-section. Each microfiber has a section with a main dimension that ranges between 0.5 mm and 1.5 mm. The term “main dimension” is understood to mean the longest dimension of the cross-section of the relevant microfiber. By way of an example, when the microfiber has a hollow tube structure with a circular cross-section, the diameter of the section is called the “main dimension”. According to another example, when the microfiber has a substantially rectangular section, the term “main dimension” is understood to mean a diagonal of this section. Advantageously, each microfiber has a main dimension of less than 1 mm. These microfibers are made of polymer material. Advantageously, the use of such a material imparts each microfiber with sufficient mechanical resistance and chemical resistance for withstanding the stresses to which they are subjected, in particular the stresses related to temperature variations, to the circulation of coolant and to the support of the electrical and/or electronic component 120. Furthermore, such a material allows the microfibers to be imparted with flexibility and deformability features, so that they can be deformed without affecting their integrity.

As described hereafter, this deformation capability allows the contact surface between the microfibers 151 and the electrical and/or electronic component 120 to be increased, and thus allows the available heat exchange surface to be increased, thus optimizing the heat exchange that is carried out.

The microfibers 151 are also at least partially surrounded by a deformable material. According to the illustrated example, these microfibers 151 are completely surrounded by this deformable material. For example, the deformable material can be silicone. This material allows the microfibers 151 of the heat exchanger 130 to be protected, while allowing these microfibers 151 to retain their deformability.

As shown in FIG. 1 and in further detail hereafter, the heat exchanger 130 is arranged in contact with at least two adjacent faces of the electrical and/or electronic component 120 that rests thereon. The term “adjacent faces” is understood to mean two faces that have at least one junction edge 125.

Advantageously, it should be noted that at least one of the faces of one of the electrical and/or electronic components 120 covered by the heat exchanger 130 is arranged facing one of the faces of the other electrical and/or electronic component 120 covered by the other heat exchanger 130. Such an arrangement allows a transfer of heat to be avoided between two electrical and/or electronic components 120 that face each other. The calories released by the faces of the electrical and/or electronic components 120 not covered by the heat exchangers for their part can be discharged via the peripheral wall 111 of the housing 110. To this end, the housing 110, and particularly the peripheral wall 111 of this housing 110, can be made of a thermally conductive material.

Finally, the heat exchanger 130 can comprise a rigid component that allows its mechanical properties to be enhanced, in order to provide the relevant electrical and/or electronic component 120 with sufficient support. According to the illustrated example, this rigid component is formed by the deformable material that surrounds the microfibers 151. In other words, the deformable material has, in itself, sufficient rigidity to support said electrical and/or electronic component 120. Alternatively, provision can be made to arrange a rigid plate between the electrical and/or electronic component 120 and the heat exchanger 130 on which it rests. For example, a plate made of a thermally conductive material, such as a metal, for example, made of aluminum, can be selected.

FIG. 1 schematically shows two alternative embodiments.

In a first alternative embodiment, the heat exchanger 131 comprises a single microfiber network 150, whereas in a second alternative embodiment, the heat exchanger 132 comprises a first microfiber network 150a and a second microfiber network 150b.

According to the first alternative embodiment, the single microfiber network 150 assumes a general shape that is substantially L-shaped. In other words, each microfiber 151 is folded so as to be simultaneously arranged facing a first face 121 of the electrical and/or electronic component 120 and a second face 122 of this electrical and/or electronic component 120, with the first face 121 and the second face 122 being adjacent. In other words, each microfiber 151 comprises at least one first portion 152 that mainly extends in a first plane P1 and at least one second portion 153 that extends in a second plane P2 intersecting the first plane P1. According to the illustrated example, the first plane P1 is more specifically perpendicular to the second plane P2. As a result, the first portions 152 of each microfiber 151 are thus arranged facing the first face 121 of the electrical and/or electronic component 120 and the second portions 153 of each microfiber 151 for their part are arranged facing the second face 122 of the electrical and/or electronic component 120. In other words, the coolant that circulates in the first portions 152 of each microfiber 151 allow the calories emitted by the first face 121 of the electrical and/or electronic component 120 to be discharged and the coolant that circulates in the second portions 153 of these microfibers 151 allows the calories emitted by the second face 122 of the electrical and/or electronic component 120 to be discharged. It is understood that such a shape of the microfibers 151 is particularly made possible by the deformable nature of these microfibers 151.

According to the second alternative embodiment, the first microfiber network 150a mainly extends in the first plane P1 and the second microfiber network 150b mainly extends in a second plane P′2 intersecting the first plane P1. According to the illustrated example, the second plane P′2 is perpendicular to the first plane P1. The microfibers 150 of the first microfiber network 150a are thus arranged facing the first face 121 of the relevant electrical and/or electronic component 120 and the microfibers 151 of the second microfiber network 150b are for their part arranged facing the second face 122 of this electrical and/or electronic component 120, with this second face 122 being, as mentioned above, adjacent to the first face 121.

Irrespective of the selected alternative embodiment, the term “arranged facing” is understood to mean the fact that the microfiber or the relevant portion of microfiber faces the stated object, and that it is arranged at a minimum distance allowing it to capture calories emitted by this object. It is therefore understood that the heat exchanger of the thermal treatment system 100 according to the invention allows, due to the deformability of the microfibers and of the deformable material it is formed by, a maximum heat exchange surface to be generated, thus ensuring optimized cooling of the electrical and/or electronic component 120.

FIG. 2 illustrates four electrical and/or electronic components 120 adapted for being thermally treated by the thermal treatment system 100 according to a second embodiment of the invention, with these electrical and/or electronic components 120 being depicted together with the heat exchangers 130 on which they respectively rest. According to this second embodiment of the invention, at least four faces of each electrical and/or electronic component 120 are covered by the heat exchanger 130 on which it rests. As a result, at least one heat exchanger is interposed between two juxtaposed electrical and/or electronic components 120. In other words, a thermal barrier is thus formed between two electrical and/or electronic components 120 that face each other, so as to avoid transferring calories between these two electrical and/or electronic components 120 that would result in an increase in their respective temperatures. In other words, this thermal barrier improves the cooling of the electrical and/or electronic components 120 thus arranged.

According to the illustrated example, the electrical and/or electronic components 120 are more specifically distributed over at least one first row 123 and over at least one second row 124 and the supply base 140 extends between the first row 123 and the second row 124. In other words, the heat exchangers 130 on which the aforementioned electrical and/or electronic components 120 rest are also distributed along this first row 123 and this second row 124. Advantageously, all these heat exchangers 130 can be supplied by the same supply base 140, irrespective of the row over which they extend.

As the housing is not shown in FIG. 2, the supply base 140 is schematically illustrated, but it is understood that this supply base 140 is, as described above, integrally formed with the housing.

As shown, each electrical and/or electronic component 120 mainly extends along a main longitudinal extension axis X, with the junction edge 125 between two adjacent faces of each electrical and/or electronic component 120 also extending parallel to this main extension axis X. Advantageously, each heat exchanger 130 extends, at least on one face, over an entire longitudinal dimension of the electrical and/or electronic component 120 that rests thereon. In other words, the heat exchanger 130 at least extends between two opposite faces along the main extension axis X of the electrical and/or electronic component 120 that rests thereon.

FIG. 2 also partially shows the supply base 140. As illustrated, at least one connector 143 is arranged at a longitudinal end of this supply base 140. Advantageously, this connector 143 allows the coolant to be conveyed within the supply base 140, and more specifically within the supply zone formed in this supply base 140, so as to allow the inlet collector boxes and then the microfibers of each heat exchanger to be supplied with coolant. Although not shown in this case, at least one other connector is formed on the supply base 140, for example, at a longitudinal end of the supply base 140 opposite the longitudinal end on which the connector 143 is formed, with this other connector being fluidly connected to the collection zone formed in the supply base 140. In other words, this other connector allows the coolant to be discharged that leaves the heat exchangers after collecting the calories emitted by the electrical and/or electronic components 120. Alternatively, the two connectors could be arranged differently, for example, on the same longitudinal end of the supply base without departing from the scope of the present invention. Advantageously, the connectors can be integrally formed with the housing and with the supply base, i.e., these connectors, the housing and the supply base form a single assembly that cannot be separated without damaging at least one of the connectors and/or the housing and/or the supply base.

In a similar manner to the above description provided with reference to FIG. 1, the heat exchanger 130 can comprise a single microfiber network, or even as many microfiber networks 150 as the faces covered by the heat exchanger that form part of the electrical and/or electronic component 120 resting thereon. In other words, according to the illustrated example in FIG. 2, each heat exchanger 130 can comprise four microfiber networks 150 independent of one another. Alternatively, each heat exchanger can comprise a single microfiber network, with each microfiber then being deformed so that at least a portion of each of them can be arranged facing one of the four relevant faces of the electrical and/or electronic component 120.

Once the heat has been exchanged between the coolant and the electrical and/or electronic component 120, this coolant is treated in order to be able to be reused. To this end, the supply base 140 is arranged on a coolant circuit, not illustrated herein, which comprises at least one component for circulating the coolant and at least one heat exchanger. The coolant thus leaves the supply base 140 heated by capturing calories emitted by the electrical and/or electronic components 120 and it is then configured to join the heat exchanger, with this heat exchanger being configured to exchange heat allowing the coolant to discharge calories thus accumulated. The coolant that has thus shed these calories can again be sent to the one or more heat exchangers via the supply base 140 in order to cool the electrical and/or electronic components 120.

Depending on the type of coolant that is used, the component for circulating the coolant can be a pump or a compression component and the coolant circuit can further comprise at least one expansion component.

FIG. 3 illustrates, schematically and as a perspective view, a heat exchanger 130 according to the first embodiment illustrated in FIG. 1. In particular, this heat exchanger 130 is shown according to the second alternative embodiment. Thus, the heat exchanger 130 comprises the first microfiber network 150a and the second microfiber network 150b that respectively extend in the first plane P1 and in the second plane P′2 perpendicular to each other.

FIG. 3 illustrates a particular arrangement in which the microfibers 151 are evenly distributed within the heat exchanger 130. As shown, each microfiber 151 assumes, according to the illustrated example, a U-shape. Each microfiber 151 thus comprises at least one inlet channel 154, the free end of which is connected to the inlet collector box 133 and at least one outlet channel 155 connected to the outlet collector box 134. In order to facilitate the reading and understanding of FIG. 3, only one inlet channel and one outlet channel are shown in their entirety for each microfiber network 150a, 150b, but it is understood that the description provided herein applies to all the microfibers 151 of each of the microfiber networks 150a, 150b.

According to the illustrated example, all the microfibers 151 of the two microfiber networks 150a, 150b are connected to the same collector boxes 133, 134. In other words, the inlet collector box 133 is configured to supply coolant to the microfibers of the first microfiber network 150a and the microfibers of the second microfiber network 150b and the outlet collector box 134 is configured to collect the coolant that leaves the microfibers of the first microfiber network 150a, as well as the coolant that leaves the microfibers of the second microfiber network 150b. As mentioned above, the inlet collector box 133 and the outlet collector box 134 are adapted for being fluidly connected to the supply base 140, and in particular the inlet collector box 133 is adapted for being connected to the supply zone of this supply base, while the outlet collector box 134 is adapted for being connected to the collection zone of this supply base. It is understood that this is only one embodiment of the invention and that provision can be made for each microfiber network to be connected to an inlet collector box and to an outlet collector box that are specific thereto, without departing from the scope of the present invention. Also, FIG. 3 illustrates a situation in which the inlet channels 154 emerge on one side of the heat exchanger, whereas the outlet channels 155 emerge on another side of the heat exchanger, but it is understood that this is only one example and that all the inlet channels 154 and outlet channels 155 of the microfibers could emerge on the same side of the heat exchanger 130 without departing from the scope of the invention.

Finally, FIG. 4 schematically illustrates a heat exchanger 130 viewed along a vertical section. This figure again shows an inlet channel 153 of a microfiber 151 of the first microfiber network 150a and an inlet channel 153 of a microfiber 151 of the second microfiber network 150b, with a free end of each of these inlet channels 153 extending into the inlet collector box 133.

As shown, this inlet collector box 133 is for its part inserted into the supply base 140, and more specifically it extends through an orifice 144 that emerges into the supply zone 141 of the supply base 140.

Advantageously, a plurality of these orifices 144 is provided on the supply base 140, with these orifices 144 being distributed over an entire longitudinal dimension of the supply base 140. It is understood that such a configuration advantageously allows connection and disconnection of a plurality of inlet collector boxes 133, i.e., a plurality of heat exchangers. Thus, all the heat exchangers 130 of the thermal treatment system according to the invention are supplied by the same supply base 140. If the number of heat exchangers and collector boxes is less than the number of orifices formed in the supply base 140, the excessive orifices simply need to be closed, for example, by means of a plug. In other words, the supply base 140 proposed herein is standard and can be used for various cooling requirements, consequently allowing economies of scale to be achieved.

Although not illustrated, the principle for connecting between the outlet collector box and the supply base, and more specifically the collection zone of this supply base, is identical to that of the connection made between the inlet collector box and the supply base illustrated in FIG. 4.

Of course, the invention is not limited to the examples that have just been described and numerous modifications can be made to these examples without departing from the scope of the invention. In particular, the features of the various alternative embodiments of the heat exchangers and of the microfiber networks can be combined together without compromising the invention.

1. A system for thermally treating at least one electrical and/or electronic component, comprising:
at least one housing that accommodates at least one heat exchanger, the electrical and/or electronic component being adapted for being accommodated in the housing and for resting on the at least one heat exchanger,
the heat exchanger comprising at least one network of microfibers, the microfibers being adapted for being traversed by a coolant and the heat exchanger being adapted for being in contact with at least two adjacent faces of the electrical and/or electronic component.

2. The thermal treatment system as claimed in claim 1, wherein the heat exchanger comprises the microfiber network and at least one deformable material, with the microfiber network being at least partially surrounded by the deformable material.

3. The thermal treatment system as claimed in claim 2, wherein the heat exchanger comprises at least one rigid component.

4. The thermal treatment system as claimed in claim 3, wherein the rigid component is included in the deformable material.

5. The thermal treatment system as claimed in claim 3, wherein the rigid component is interposed between the deformable material and the electrical and/or electronic component.

6. The thermal treatment system as claimed in claim 3, wherein the rigid component is an aluminum plate.

7. The thermal treatment system as claimed in claim 1, comprising two heat exchangers, with at least one electrical and/or electronic component being configured to rest, respectively, on each of these heat exchangers, with each heat exchanger comprising at least one microfiber network and each heat exchanger being adapted for being in contact with at least two adjacent faces of the electrical and/or electronic component that is configured to rest thereon.

8. The thermal treatment system as claimed in claim 7, wherein at least one of the faces of one of the electrical and/or electronic components adapted for being covered by one of the heat exchangers is to be arranged facing one of the faces of the other electrical and/or electronic component adapted for being covered by the other heat exchanger.

9. The thermal treatment system as claimed in claim 1, wherein the heat exchanger comprises at least one first microfiber network and at least one second microfiber network distinct from the first microfiber network, with the first microfiber network being adapted for mainly extending facing a first face of the electrical and/or electronic component and the second microfiber network being adapted for mainly extending facing a second face of the electrical and/or electronic component, with the first face of the electrical and/or electronic component being adjacent to the second face of this electrical and/or electronic component.

10. The thermal treatment system as claimed in claim 9, wherein the first microfiber network mainly extends in a first plane and wherein the second microfiber network mainly extends in a second plane, with the first plane being perpendicular to the second plane.

11. The thermal treatment system as claimed in claim 1, wherein the heat exchanger comprises a single microfiber network, with the microfibers of this single microfiber network each extending in a first plane and in a second plane intersecting each other.

12. The thermal treatment system as claimed in claim 11, wherein each microfiber of the microfiber network comprises at least one first portion adapted for being arranged facing a first face of the electrical and/or electronic component and at least one second portion adapted for being arranged facing a second face of the electrical and/or electronic component, with the second face being adjacent to the first face.

13. The thermal treatment system as claimed in claim 1, wherein the heat exchanger is configured to extend over an entire longitudinal dimension of the electrical and/or electronic component configured to rest thereon.

14. The thermal treatment system as claimed in claim 1, wherein the microfibers of the microfiber network are evenly arranged within the heat exchanger.

15. The thermal treatment system as claimed in claim 1, wherein the microfibers of the microfiber network are randomly arranged within the heat exchanger.

16. The thermal treatment system as claimed in claim 1, wherein the housing accommodates at least one fluid supply base of the heat exchanger, with the heat exchanger being configured to exchange heat between the coolant and the electrical and/or electronic component, with the supply base being configured to allow routing, and/or respectively discharging, of the coolant into, and/or respectively out of, the microfibers of the heat exchanger.

17. The thermal treatment system as claimed in claim 16, wherein the supply base is integrally formed with the housing.

18. The thermal treatment system as claimed in claim 16, wherein each microfiber of the heat exchanger comprises at least one inlet channel and at least one outlet channel, with the inlet channels of the microfibers being fluidly connected to an inlet collector box configured to distribute the coolant within the microfibers and the outlet channels of the microfibers being fluidly connected to an outlet collector box configured to collect the coolant leaving the microfibers.

19. The thermal treatment system as claimed in claim 18, wherein all the inlet channels of all the microfibers of the heat exchanger are fluidly connected to the same inlet collector box and wherein all the outlet channels of all the microfibers of the heat exchanger are fluidly connected to the same outlet collector box.

20. The thermal treatment system as claimed in claim 19, wherein the inlet collector box is fluidly connected to the supply base and wherein the outlet collector box is fluidly connected to the supply base.

21. The thermal treatment system as claimed in claim 20, wherein the supply base comprises at least one supply zone configured to supply the inlet collector box with coolant and at least one collection zone configured to collect the coolant leaving the outlet collector box.

22. The thermal treatment system as claimed in claim 20, wherein the supply base is configured to be fluidly connected to a plurality of inlet collector boxes and to a plurality of outlet collector boxes.

23. The thermal treatment system as claimed in claim 16, comprising a plurality of heat exchangers distributed over at least two rows, and wherein the supply base extends between the two rows of heat exchangers.

24. An electrical energy storage device, comprising: at least one electrical energy storage component and at least one thermal treatment system as claimed in claim 1, wherein the at least one electrical and/or electronic component that rests on the at least one heat exchanger of the thermal treatment system is an electrical energy storage component.

25. A vehicle comprising at least one electrical energy storage device as claimed in claim 24.
